(19) United States
(12) Patent Application Publication
(10) Pub. No.: US 2006/0011930 A1
(43) Pub. Date: Jan. 19, 2006

(54) Semiconductor photodetecting device and method of manufacturing the same

(76) Inventors: Seiichiro Tamai, Toyono-gun (JP); Tetsuzo Ueda, Toyonaka-shi (JP)

Correspondence Address: WENDEROTH, LIND & PONACK, L.L.P., 2033 K STREET N. W., SUITE 800, WASHINGTON, DC, 20006-1021, US

(21) Appl. No.: 11/180,638

(22) Filed: Jul. 14, 2005

(30) Foreign Application Priority Data
Jul. 16, 2004 (JP) 2004-209677

(51) Int. Cl. H01L 33/00; H01L 21/00

(52) U.S. Cl. 257/85; 438/48

(57) ABSTRACT

An object of the present invention is to provide a semiconductor photodetecting device that enables a solid-state image sensor to meet requirement of higher quality imaging and more reduction in cost, and the semiconductor photodetecting device includes a semiconductor substrate, and an epitaxial layer that is formed on the semiconductor substrate by an epitaxial growth method and a vapor phase growth method. The epitaxial layer is formed by sequentially stacking a first pn junction layer, a first insulating layer, a second pn junction layer, a second insulating layer, and a third pn junction layer. The first pn junction layer, the second pn junction layer, and the third pn junction layer have respective band gaps which are different from one another, by changing their crystalline structures or film compositions.

### BACKGROUND OF THE INVENTION

1. Field of the Invention

The present invention relates to a semiconductor photodetecting device and a method of manufacturing it, and more particularly to a semiconductor photodetecting device for a charge-coupled device (CCD) or a complementary metal-oxide-semiconductor (CMOS) solid-state image sensor and a method of manufacturing it. (2) Description of the Related Art

CCD or MOS solid-state image sensors are embedded in digital still cameras, camcorders and the like. Such solid-state image sensors convert light incident on their semiconductor photodetecting devices which are made of semiconductor materials into electric charges. In the CCD solid-state image sensor, the generated signal charges are accumulated in potential wells, and then transferred. In the MOS solid-state image sensor, on the other hand, the generated signal charges are read out as voltage directly from the semiconductor photodetecting devices using MOS transistors. Imaging areas in those solid-state image sensors, in which the semiconductor photodetecting devices are two-dimensionally arranged, have red-green-blue (RGB) primary color filters with the Bayer or stripe type color array for colorization (for example, refer to Japanese Laid-Open Patent Application No. 05-183139 publication).

FIG. 1 is a schematic cross-sectional view showing a structure of a semiconductor photodetecting device in a conventional MOS solid-state image sensor and its periphery.

The conventional solid-state image sensor is comprised of: a plurality of semiconductor photodetecting devices 21 which are a plurality of n-type regions formed in a p-type silicon substrate 20; a color filter 22 which is placed at light incident side of the semiconductor photodetecting devices 21; and a plurality of output amplifiers 23, which have each MOS transistor 24 so as to be connected with each semiconductor photodetecting device 21, and which convert signal charges into voltage, amplify the voltage, and output it.

It should be noted that RGB primary colors in the color filter 22 are arranged in the Bayer color array pattern as shown in FIG. 2.

In recent years, it has been required to provide a solid-state image sensor with higher performance, higher quality imaging, more reduction in cost and size, and the like.

However, the conventional solid-state image sensor selects, through the color filter, red, green and blue light from incident light. The semiconductor photodetecting devices which convert the selected red, green and blue light into electric charges are arranged on the same plane. This results in a problem that when it comes to a smaller chip, the conventional solid-state image sensor has smaller photosensing areas corresponding to respective color pixels and eventually reduces photodetecting sensitivity and thus reduces color reproducibility of images, so that the conventional solid-state image sensor fails to meet the requirement of higher quality imaging or more reduction in cost.

In view of the foregoing, it is an object of the present invention to provide a semiconductor photodetecting device that solves the above problem and thus enables a solid-state image sensor to meet the requirements of higher quality imaging and more reduction in cost. In order to achieve the above object, the semiconductor photodetecting device according to the present invention includes a plurality of pn junction layers that are stacked wherein the plurality of pn junction layers have respective band gaps which are different from one another. Here, the semiconductor photodetecting device may include a first pn junction layer, a second pn junction layer above the first pn-juncction, and a third pn junction layer above the second pn junction layer, wherein the band gap of the first pn junction layer is smaller than the band gap of the second pn junction layer, and the band gap of the second pn junction layer is smaller than the band gap of the third pn junction layer. Here, the band gap of the first pn junction layer may be smaller than energy corresponding to a red light wavelength, the band gap of the second pn junction layer may be smaller than energy corresponding to a green light wavelength, and the band gap of the third pn junction layer may be smaller than energy corresponding to a blue light wavelength. A pn junction in the first pn junction layer may be positioned to have highest photodetecting sensitivity to the red light, a pn junction in the second pn junction layer may be positioned to have highest photodetecting sensitivity to the green light, and a pn junction in third second pn junction layer may be positioned to have highest photodetecting sensitivity to the blue light. Further, the plurality of pn junction layers may be made of a semiconductor material including silicon. One of the plurality of pn junction layers may be made of one of amorphous silicon, micro-crystal silicon, single-crystal silicon carbide, amorphous silicon carbide, and micro-crystal silicon carbide.

Thereby, all of red, green and blue light components of the incident light can be used in a single semiconductor photodetecting device, which can result in increase in efficiency of available light in the semiconductor photodetecting device and improvement in color reproducibility of images in the solid-state image sensor. Accordingly, the semiconductor photodetecting device according to the present invention enables the solid-state image sensor to meet the requirement of still higher quality imaging. Furthermore, the semiconductor photodetecting device according to the present invention can perform RGB primary color sensing at the same location so that it enables the solid-state image sensor to achieve higher resolution of images. It is further possible to perform color separation without using a color filter in the solid-state image sensor, and also without using multiple kinds of semiconductor photodetecting devices for converting only one of red, green, and blue light into electric charges, so that the semiconductor photodetecting device according to the present imvention enables the solid-state image sensor to meet the requirement of further reduction in cost and size. It is still further possible to design the first pn junction layer to have its absorption peak in a red-light wavelength range, the second pn junction layer to have its absorption peak in a green-light wavelength range, and the third pn junction layer to have its absorption peak in a blue-light wavelength range, so that the semiconductor photodetecting device according to the present invention enables the solid-state image sensor to further improve the color reproducibility of images, and enables to realize the solid-state image sensor as a smaller-dimension chip.

Futhermore, the semiconductor photodetecting device may further include an insulating layer that is formed between the pn junction layer and the another pn junction layer, the another pn junction layer being adjacent to the pn junction layer. The insulating layer may be made of a semiconductor material including oxygen. The insulating layer may be made of one of silicon dioxide and silicon nitride.

Accordingly, it is possible to flexibly design arrangement of p- and n-type layers in each pn junction layer without being restricted by arrangement of p- and n-type layers in another pn junction layer, so that the present invention can realize the semiconductor photodetecting device with high design flexibility.

Still futher, the insulating layer selectively may pass light of a predetermined wavelength through. The insulating layer may be formed by stacking a plurality of types of layers whose refractive indices are different from one another.

Accordingly, it is possible to completely cut off light leakage onto a wrong substrate which converts different light, in order to perform color separation of the incident light more distinctly, so that the semiconductor photodetecting device according to the present invention enables the solid-state image sensor to improve resolution of images.

In addition, the present invention can be implemented as a method of manufacturing a semiconductor photodetecting device, the method including: forming a first pn junction layer on a substrate; forming a first insulating layer on the first pn junction layer; forming a second pn junction layer on the first insulating layer; forming a second insulating layer on the second pn junction layer; and forming a third pn junction layer on the second insulating layer, wherein in the forming of the first pn junction layer, the second pn junction layer, and the third pn junction layer, band gaps of the first pn junction layer, the second pn junction layer, and the third pn junction layer are different from one another. Further, the forming of the first insulating layer and the second insulating layer may include forming the first insulating layer and the second insulating layer by implanting an impurity into the first pn junction layer and the second pn junction layer by ion implantation. The forming of the first insulating layer and the second insulating layer may include forming the first insulating layer and the second insulating layer by implanting oxygen ion by the ion implantation. The forming of the first pn junction layer may include forming of the first pn junction by positioning a pn junction in the first pn junction layer to have highest photodetecting sensitivity to red light, the forming of the second pn junction layer may include forming of the second pn junction layer by positioning a pn junction in the second pn junction layer to have highest photodetecting sensitivity to green light, and the forming of the third pn junction layer may include forming of the third pn junction layer by positioning a pn junction in the third pn junction layer to have highest photodetecting sensitivity to blue light.

Accordingly, it is possible to implement a method of manufacturing the semiconductor photodetecting device that enables the solid-state image sensor to meet the requirement of higher quality imaging. It is also possible to implement a method of manufacturing the semiconductor photodetecting device that enables the solid-state image sensor to achieve high resolution of images. It is further possible to implement a method of manufacturing the semiconductor photodetecting device that enables the solid-state image sensor to achieve reduction in size.

Here, the forming of the first pn junction layer, the second pn junction layer, and the third pn junction layer may include forming the first pn junction layer, the second pn junction layer, and the third pn junction layer by epitaxial growth..

Further, the semiconductor photodetecting device can be easily manufactured, so that it is possible to implement a method of manufacturing the semiconductor photodetecting device that prevents its cost from being increased by yield. It is also possible to implement a method of manufacturing the semiconductor photodetecting device that is made of a material having good crystallinity.

Here, the forming of the second pn junction layer and the third pn junction layer may include forming the second pn junction layer and the third pn junction layer by forming one of a polycrystalline film and an amorphous film and then applying the film with one of heating and irradiating with light on to change crystallinity of the film. The forming of the second pn junction layer and the third pn junction layer may include forming the second pn junction layer and the third pn junction layer by irradiating laser light on the film to change crystallinity of the film.

Accordingly, the second pn junction layer and the third pn junction layer are formed without being restricted by the first insulating layer and the second insulating layer which are substrates for crystallization and the like so that it is possible to select a semiconductor material of the pn junction layers with high flexibility, in other words, it is possible to implement a method of manufacturing the semiconductor photodetecting device with high design flexibility.

As described above, according to the semiconductor photodetecting device of the present invention, it is possible to implement the semiconductor photodetecting device that enables the solid-state image sensor to meet the requirement of higher quality imaging and more reduction in cost, and the method of manufacturing such device. It is also possible to implement the semiconductor photodetecting device that enables the solid-state image sensor to achieve high resolution of images, and the method of manufacturing such device. It is further possible to implement the semiconductor photodetecting device that enables the solid-state image sensor to achieve reduction in size, and the method of manufacturing such device. It is still further possible to realize the semiconductor photodetecting device with high design flexibility, and the method of manufacturing such device.

Accordingly, the present invention provides the semiconductor photodetecting device that enables the solid-state image sensor to meet the requirement of higher quality imaging and more reduction in size, and the method manufacturing such device, resulting in the solid-state image sensor with high-performance which is highly suitable for practical use.

### FURTHER INFORMATION ABOUT TECHNICAL BACKGROUND TO THIS APPLICATION

The disclosure of Japanese Patent Application No. 2004-209677 filed on Jul. 16, 2004 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a schematic cross-sectional view showing a structure of a semiconductor photodetecting device in a conventional MOS solid-state image sensor and its periphery;

FIG. 2 is a diagram showing a RGB primary color array in a color filter;

FIG. 3 is a schematic cross-sectional view showing a structure of a semiconductor photodetecting device according to a first embodiment of the present invention;

FIG. 4A is a schematic cross-sectional view showing a method of manufacturing the semiconductor photodetecting device according to the first embodiment;

FIG. 4B is a schematic cross-sectional view showing the method of manufacturing the semiconductor photodetecting device according to the first embodiment;

FIG. 4C is a schematic cross-sectional view showing the method of manufacturing the semiconductor photodetecting device according to the first embodiment;

FIG. 5 is a schematic cross-sectional view showing a structure of a semiconductor photodetecting device according to a second embodiment of the present invention;

FIG. 6A is a schematic cross-sectional view showing a structure of a first insulating layer;

FIG. 6B is a schematic cross-sectional view showing a structure of a second insulating layer;

FIG. 7A is a schematic cross-sectional view showing a method of manufacturing the semiconductor photodetecting device according to the second embodiment;

FIG. 7B is a schematic cross-sectional view showing the method of manufacturing the semiconductor photodetecting device according to the second embodiment;

FIG. 7C is a schematic cross-sectional view showing the method of manufacturing the semiconductor photodetecting device according to the second embodiment; and

FIG. 7D is a schematic cross-sectional view showing the method of manufacturing the semiconductor photodetecting device according to the second embodiment.

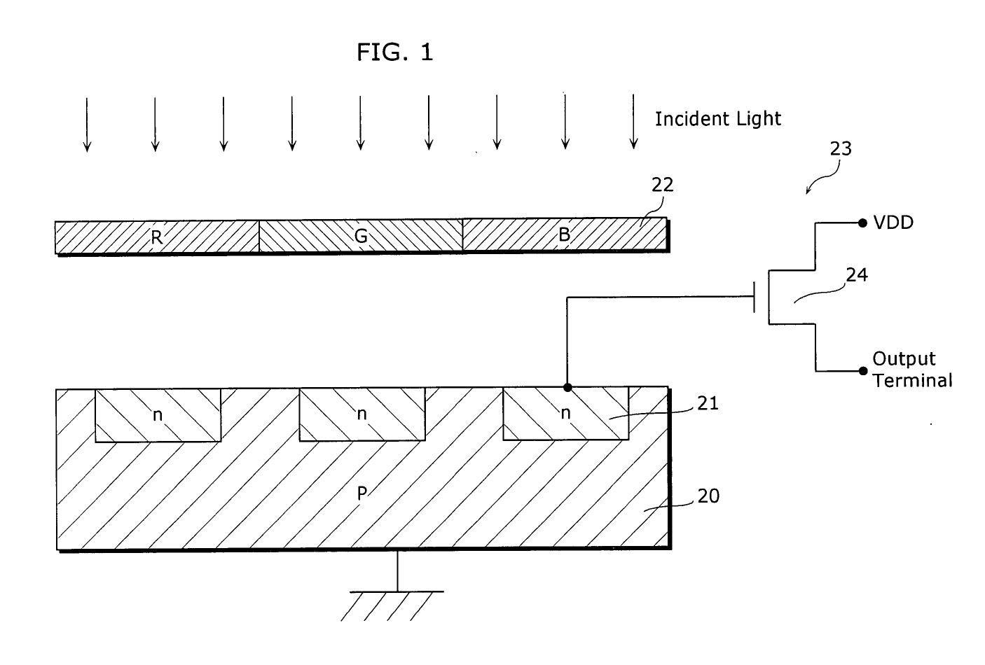

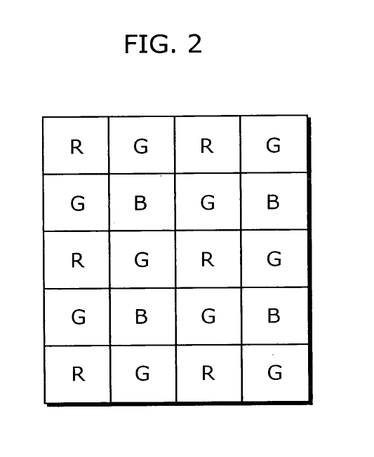

### DESCRIPTION OF THE PREFERRED EMBODIMENTS(S)

The following describes the semiconductor photodetecting device according to embodiments of the present invention with reference to the drawings.

### FIRST EMBODIMENT

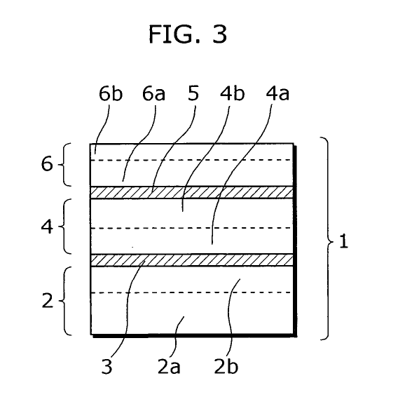

FIG. 3 is a schematic cross-sectional view showing a structure of a semiconductor photodetecting device according to a first embodiment of the present invention.

The semiconductor photodetecting device has: a semiconductor substrate that is made of silicon and the like (not shown); and an epitaxial layer 1 that is formed on the semiconductor substrate by epitaxial growth. The epitaxial layer 1 is formed by sequentially stacking a first pn junction layer 2, a first insulating layer 3, a second pn junction layer 4, a second insulating layer 5, and a third pn junction layer 6. Note that light incident on the semiconductor photodetecting device enters on the third pn junction layer 6, the second pn junction layer 4, and the first pn junction layer 2, in this order.

The first pn junction layer 2 is comprised of an n-type layer 2a and a p-type layer 2b. The second pn junction layer 4 is comprised of an n-type layer 4a and a p-type layer 4b. The third pn junction layer 6 is comprised of an n-type layer 6a and a p-type layer 6b.

Note that all of the first pn junction layer 2, the second pn junction layer 4, and the third pn junction layer 6 may be made of single-crystal silicon, or each junction may have an optical band gap that is different from another. One example of the junctions having different optical band gaps is that the first pn junction layer 2 has a band gap that is smaller than energy corresponding to a red light wavelength, the second pn junction layer 4 has a band gap that is greater than the band gap of the first pn junction layer 2 but smaller than energy corresponding to a green light wavelength, the third pn junction layer 6 has a band gap that is greater than the band gap of the second pn junction layer 4 but smaller than energy corresponding to a blue light wavelength.

As semiconductor materials of the first pn junction layer 2, the second pn junction layer 4, and the third pn junction layer 6, it is preferable to select a material or a composition with highest photodetecting sensitivity in the layer, from silicon, amorphous silicon, micro-crystal silicon, silicon carbide, amorphous silicon carbide, and micro-crystal silicon carbide, for example. More specifically, single-crystal silicon suits a semiconductor material of the first pn junction layer 2, micro-crystal or amorphous silicon suits a semiconductor material of the second pn junction layer 4, and single-crystal silicon carbide (cubic crystal, preferably) suits a semiconductor material of the third pn junction layer 6.

The first pn junction layer 2, the second pn junction layer 4, and the third pn junction layer 6 have respective pn junction at different positions. Relative positions between a light incident surface of the semiconductor photodetecting device and the respective pn junction in the pn junction layers differ from one another depending on the respective pn junction layers. The first pn junction layer 2 has its pn junction that is positioned depending on an absorption depth of red light into the semiconductor material of the first pn junction layer 2, that is, positioned to have the highest photodetecting sensitivity to red light. The second pn junction layer 4 has its pn junction that is positioned depending on an absorption depth of green light into the semiconductor material of the second pn junction layer 4, that is, positioned to have the highest photodetecting sensitivity to green light. The third pn junction layer 6 has its pn junction that is positioned depending on an absorption depth of blue light into the semiconductor material of the third pn junction layer 6, that is, positioned to have the highest photodetecting sensitivity to blue light.

If the semiconductor materials of the first pn junction layer 2, the second pn junction layer 4, and the third pn junction layer 6 are, for example, single-crystal silicon, micro-crystal or amorphous silicon, single-crystal silicon carbide, respectively, pn junction depths of the first pn junction layer 2, the second pn junction layer 4, and the third pn junction layer 6 from the light incident surface of the semiconductor photodetecting device are 3 μm, 1 μm, and 0.4 μm, respectively.

The first insulating layer 3 is formed by doping an impurity into a pn junction of the first pn junction layer 2 to be a high-resistance layer, and electrically isolates the first pn junction layer 2 from the second pn junction layer 4. The second insulating layer 5 is formed by doping an impurity into a pn junction of the second pn junction layer 4 to form a high-resistance layer, and electrically isolates the second pn-juncction 4 from the third pn junction layer 6.

Impurities enabling the first pn junction layer 2 and the second pn junction layer 4 to form deep levels are used as the impurities to be doped into the first pn junction layer 2 and the second pn junction layer 4 for forming the first insulating layer 3 and the second insulating layer 5. For example, if the semiconductor material of the second pn junction layer 4 is silicon, the impurity is oxygen, nitrogen and the like. In this case, the second insulating layer 5 is made of silicon dioxide, silicon nitride, or the like.

In the semiconductor photodetecting device having the above-described structure, the first pn junction layer 2, the second pn junction layer 4, and the third pn junction layer 6 form respective photodiodes that convert light of specific wavelengths into electric charges. For example, the first pn junction layer 2 converts incident light of a wavelength ranging from 575 nm to 700 nm, which is red light, into electric charges. The second pn junction layer 4 converts incident light of a wavelength ranging from 490 nm to 575 nm, which is green light, into electric charges. The third pn junction layer 6 converts incident light of a wavelength ranging from 400 nm to 490 nm, which is blue light, into electric charges.

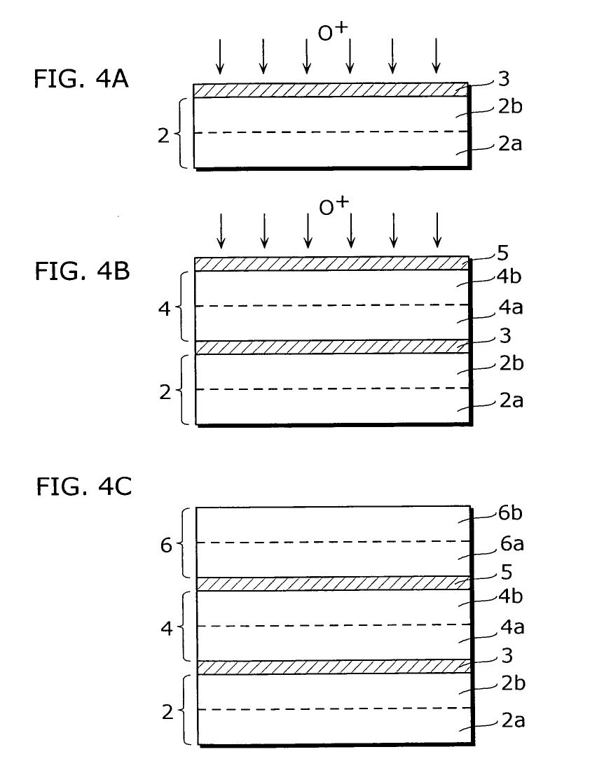

Next, the following describes a method of manufacturing the semiconductor photodetecting device having the above-described structure, with reference to schematic cross-sectional views of the semiconductor photodetecting device shown in FIGS. 4A, 4B, and 4C.

Referring firstly to FIG. 4A, the first pn junction layer 2 made of silicon is formed on the semiconductor substrate (not shown) made of silicon by epitaxial growth, and then an oxygen ion is implanted into a p-type layer 2b in the first pn junction layer 2. Then, the first pn junction layer 2 is applied with a heat treatment at 900° C. in vacuum so that the implanted oxygen chemically reacts with the silicon, resulting in the first insulating layer 3.

Referring next to FIG. 4B, the second pn junction layer 4 made of silicon is formed on the first insulating layer 3 by epitaxial growth, and then an oxygen ion is implanted into a p-type layer 4b in the second pn junction layer 4. Then, the second pn junction layer 4 is applied with a heat treatment at 900° C. in vaccum so that the implanted oxygen chemically reacts with the silicon, resulting in the second insulating layer 5.

Referring next to FIG. 4C, the third pn junction layer 6 made of silicon carbide is formed on the second insulating layer 5 by epitaxial growth. Here, a vapor phase growth method is used as the epitaxial growth.

According to the semiconductor photodetecting device of the first embodiment as described above, the first pn junction layer 2 converts red light into electric charges, the second pn junction layer 4 converts green light into electric charges, and the third pn junction layer 6 converts blue light into electric charges. Thereby all of red, green and blue light components of the incident light can be used in a single semiconductor photodetecting device, which can result in increase in efficiency of available light in the semiconductor photodetecting device and improvement in color reproducibility of images in the solid-state image sensor. Accordingly, the semiconductor photodetecting device according to the first embodiment enables the solid-state image sensor to meet the requirement of higher quality imaging. It is also possible to perform RGB primary color sensing at the same location so that the semiconductor photodetecting device according to the first embodiment enables the solid-state image sensor to achieve high resolution of images. It is further possible to perform color separation without using a color filter in the solid-state image sensor, and also without using multiple kinds of semiconductor photodetecting devices for converting only one of red, green, and blue light into electric charges, so that the semiconductor photodetecting device according to the first embodiment enables the solid-state image sensor to meet the requirement of further reduction in cost and size.

Furthermore, according to the semiconductor photodetecting device of the first embodiment, the first pn junction layer 2, the second pn junction layer 4, and the third pn junction layer 6 have the respective band gaps that are different from another. Thereby it is possible to design the first pn junction layer 2 to have an absorption peak in a red-light wavelength range, the second pn junction layer 4 to have an absorption peak in a green-light wavelength range, and the third pn junction layer 6 to have an absorption peak in a blue-light wavelength range, so that the semiconductor photodetecting device according to the first embodiment enables the solid-state image sensor to further improve the color reproducibility of images, and enables to realize the solid-state image sensor as a smaller-dimension chip.

For example, if silicon, micro-crystal or amorphous silicon, single-crystal silicon carbide are used as the semiconductor materials of the first pn.junction layer 2, the second pn junction layer 4, and the third pn junction layer 6, respectively, then the most sensitive wavelengths in the first pn junction layer 2, the second pn junction layer 4, and the third pn junction layer 6 are 750 nm, 550 nm, and 450 nm, respectively.

Still Further, the semiconductor photodetecting device according to the first embodiment is formed by epitaxial growth. Thereby, crystallinity in the semiconductor photodetecting device can be improved to enhance the sensitivity, so that the semiconductor photodetecting device according to the first embodiment enables the solid-state image sensor to further improve the color reproducibility of images.

Still further, according to the semiconductor photodetecting device of the first embodiment, the first insulating layer and the second insulating layer are formed between the first pn junction layer 2 and the second pn junction layer 4, and between the second pn junction layer 4 and the third pn junction layer 6, respectively. Thereby it is possible to flexibly design arrangement of p- and n-type regions in the pn junction layer without being restricted by arrangement of p- and n-type regions in another pn junction layer, so that the first embodiment can realize the semiconductor photodetecting device with high design flexibility. It is also possible to completely insulate the pn junction layer from another pn junction layer thereby reducing leakage current, so that the semiconductor photodetecting device according to the first embodiment enables the solid-state image sensor to meet the requirement of higher quality imaging.

### SECOND EMBODIMENT

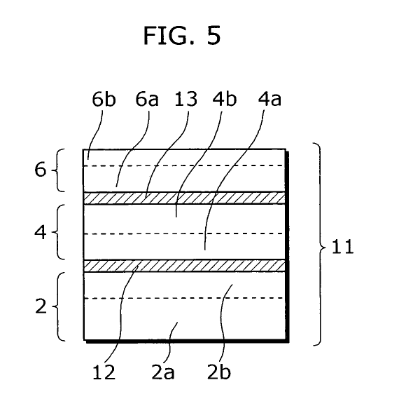

FIG. 5 is a schematic cross-sectional view showing a structure of a semiconductor photodetecting device according to a second embodiment of the present invention. Note that the reference numerals in FIG. 3 are assigned to identical elements in FIG. 5 so that the details of those elements are same as described above.

The semiconductor photodetecting device has a semiconductor substrate (not shown) and an epitaxial layer 11 that is formed on the semiconductor substrate by epitaxial growth. The epitaxial layer 11 is formed by sequentially stacking the first pn junction layer 2, a first insulating layer 12, the second pn junction layer 4, a second insulating layer 13, and the third pn junction layer 6.

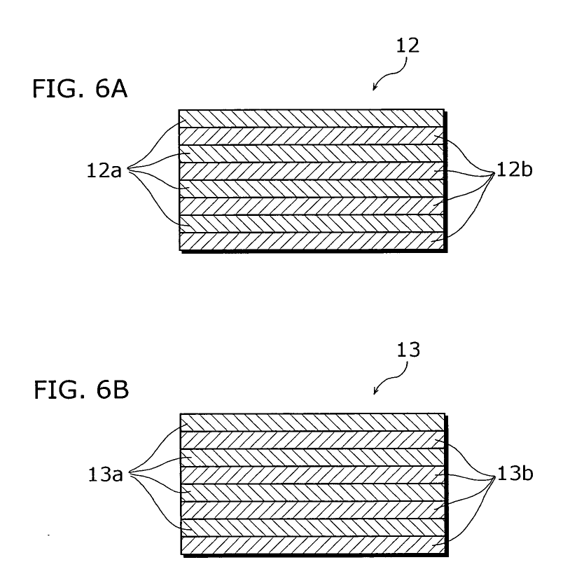

FIG. 6A is a schematic cross-sectional view showing a structure of the first insulating layer 12, and FIG. 6B is a schematic cross-sectional view showing a structure of the second insulating layer 13.

The first insulating layer 12 has a multilayer structure, and electrically isolates the first pn junction layer 2 from the second pn junction layer 4. In the first insulating layer 12, a refractive index periodic structure is formed in a stacked direction. More specifically, a low-refractive layer 12a made of a low-refractive material is used as odd-numbered layers including a top layer, and a high-refractive layer 12b made of a high-refractive material is used as even-numbered layers including the second layer, which are arranged to form one on the other for several times.

The second insulating layer 13 has a multilayer structure, and electrically isolates the second pn junction layer 4 from the third pn junction layer 6. In the second insulating layer 13, a refractive index periodic structure is formed in a stacked direction. More specifically, a low-refractive layer 13a made of a low-refractive material is used as odd-numbered layers including a top layer, and a high-refractive layer 13b made of a high-refractive material is used as even-numbered layers including the second layer, which are arranged to form one on the other for several times.

Examples of the material of the low-refractive layers 12a and 13a are silicon dioxide and the like, and examples of the material of the high-refractive layers 12b and 13b are titanium dioxide, tantalum pentoxide, and the like. Note that it is preferable that the materials pass visible light through in order to prevent absorption loss. If the material of the low-refractive layers 12a and 13a is silicon dioxide, and the material of the high-refractive layers 12b and 13b is titanium dioxide, a thickness of the low-refractive layer 12a is set to 94 nm, a thickness of the high-refractive layer 12b is set to 55 nm, a thickness of the low-refractive layer 13a is set to 77 nm, and a thickness of the high-refractive layer 13 b is set to 45nm. With the structure with those thicknesses, the insulating layer 12 is able to have high reflectivity for light of a wavelength of 550 nm, and the insulating layer 13 is able to have high reflectivity for light of a wavelength of 450 nm. Therefore, with such a structure, in the second pn junction layer and the first pn junction layer, their photodetecting sensitivity can be further increased.

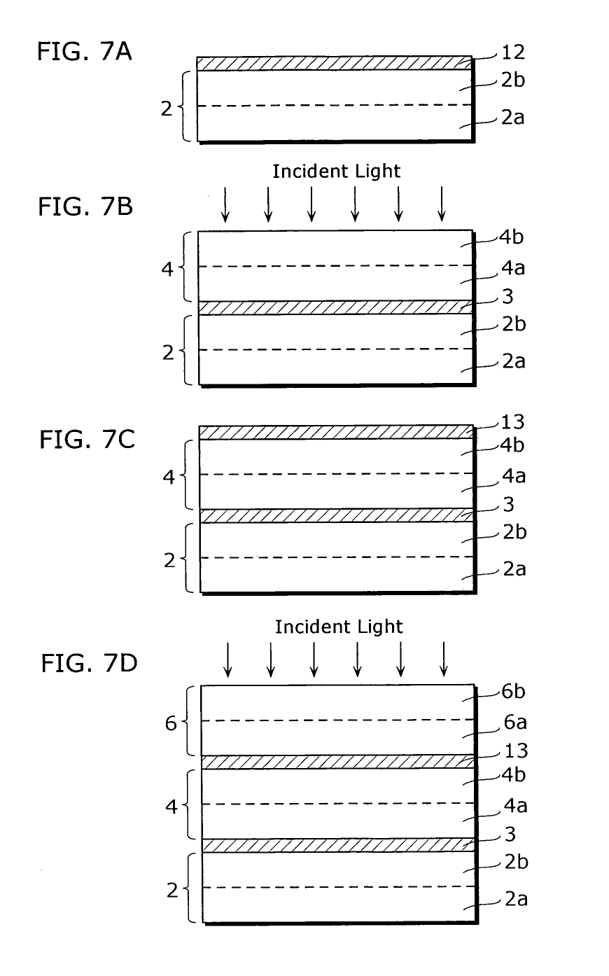

Next, the following describes a method of manufacturing the semiconductor photodetecting device according to the second embodiment, with reference to schematic cross-sectional views of the semiconductor photodetecting device shown in FIGS. 7A, 7B, 7C and 7D. Note that the reference numerals in FIG. 5 are assigned to identical elements throughout the separate views in FIGS. 7A, 7B, 7C and 7D so that the details of those elements are same as described above.

Referring now to FIG. 7A, the first pn junction layer 2 made of silicon is formed on a silicon substrate (not shown) by epitaxial growth. Then, by a plasma chemical vapor deposition (CVD) method, the low-refractive layer 12a made of silicon dioxide and the high-refractive layer 12b made of titanium dioxide are formed on the first pn junction layer 2 to be arranged to form one on the other for several times, resulting in the first insulating layer 12.

Referring next to FIG. 7B, a semiconductor layer made of polycrystalline or amorphous silicon is formed on the first insulating layer 12 by the plasma-CVD method, and then light, for example excimer laser light, is irradiated on the semiconductor layer to be micro crystallized, resulting in the second pn junction layer 4 made of micro-crystal silicon.

Referring next to FIG. 7C, by the plasma-CVD method, the low-refractive layer 13a made of silicon dioxide and the high-refractive layer 13b made of titanium dioxide are formed on the second pn junction layer 4 to be arranged to form one on the other for several times, resulting in the second insulating layer 13.

Referring next to FIG. 7D, a semiconductor layer made of polycrystalline or amorphous silicon carbide is formed on the second insulating layer 13 by the plasma-CVD method, and then light, for example excimer laser light, is irradiated on the semiconductor layer to be further crystallized, resulting in the third pn junction layer 6 made of micro-crystal or single-crystal silicon carbide.

According to the semiconductor photodetecting device of the second embodiment as described above, resulting from the same effects as described in the semiconductor photodetecting device of the first embodiment, it is possible to implement a semiconductor photodetecting device that enables the solid-state image sensor to meet the requirement of higher quality imaging. It is also possible to implement the semiconductor photodetecting device that enables the solid-state image sensor to achieve high resolution of images. It is further possible to implement the semiconductor photodetecting device that enables the solid-state image sensor to meet the requirement of further reduction in cost and size.

Furthermore, according to the semiconductor photodetecting device of the second embodiment, the first insulating layer 12 and the second insulating layer 13 have the refractive index periodic structures, in which a transmission wavelength of incident light depends on each layer thickness and each refractive index of the low-refractive layers 12a and 13a, and the high-refractive layers 12b and 13b, so that the first insulating layer 12 and the second insulating layer 13 have a function of serving as a filter that has high reflectivity for light of a specific wavelength. Thereby it is possible to completely guide all of the red light, green light, and blue light to each of the first pn junction layer 2, the second pn junction layer 4, and the third pn junction layer 6, so that the semiconductor photodetecting device according to the second embodiment enables the solid-state image sensor to further improve the color reproducibility of images. At the same time, the photodetecting devices for detecting RGB primary colors are stacked vertically, thereby enabling to realize the image sensor as a smaller-dimension chip.

Moreover, the semiconductor photodetecting device of the second embodiment has a re-crystallization process during manufacturing the semiconductor photodetecting device. Thereby, the second pn junction layer 4 and the third pn junction layer 6 are formed without being restricted by arrangement of the first insulating layer 12 and the second insulating layer 13 which are substrates for crystallization or the like, so that for the semiconductor photodetecting device according to the second embodiment it is possible to select a semiconductor material of the pn junction layers with high flexibility, in other words, it is possible to realize the semiconductor photodetecting device with high design flexibility.

Although only some exemplary embodiments of the semiconductor photodetecting device according to the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

For example, the above embodiments have described that the first insulating layer and the second insulating layer are formed between the first pn junction layer and the second pn junction layer, and between the second pn junction layer and the third pn junction layer, respectively. However, it should be appreciated that the first insulating layer between the first pn junction layer and the second pn junction layer, and the second insulating layer between the second pn junction layer and the third pn junction layer are not necessarily formed.

Furthermore, the above embodiments have described that the semiconductor layer made of polycrystalline or amorphous silicon is irradiated with light to be crystallized, but it should be appreciated that the semiconductor layer may be heated to be crystallized.

### INDUSTRIAL APPLICABILITY

The present invention can be utilized for a semiconductor photodetecting device, and more particularly for a semiconductor photodetecting device in a CCD or CMOS solid-state image sensor.

What is claimed is:

1. A semiconductor photodetecting device which converts incident light into electric charges, said device comprising a plurality of pn junction layers that are stacked wherein said plurality of pn junction layers have respective band gaps which are different from one another.

2. The semiconductor photodetecting device according to claim 1 comprising
a first pn junction layer, a second pn junction layer above said first pn-juncction, and a third pn junction layer above said second pn junction layer,
wherein the band gap of said first pn junction layer is smaller than the band gap of said second pn junction layer, and
the band gap of said second pn junction layer is smaller than the band gap of said third pn junction layer.

3. The semiconductor photodetecting device according to claim 2,
wherein the band gap of said first pn junction layer is smaller than energy corresponding to a red light wavelength,
the band gap of said second pn junction layer is smaller than energy corresponding to a green light wavelength, and
the band gap of said third pn junction layer is smaller than energy corresponding to a blue light wavelength.

4. The semiconductor photodetecting device according to claim 3,
wherein a pn junction in said first pn junction layer is positioned to have highest photodetecting sensitivity to the red light,
a pn junction in said second pn junction layer is positioned to have highest photodetecting sensitivity to the green light, and
a pn junction in third second pn junction layer is positioned to have highest photodetecting sensitivity to the blue light.

5. The semiconductor photodetecting device according to claim 4, further comprising
an insulating layer that is formed between said pn junction layer and said another pn junction layer, said another pn junction layer being adjacent to said pn junction layer.

6. The semiconductor photodetecting device according to claim 5,
wherein said insulating layer selectively passes light of a predetermined wavelength through.

7. The semiconductor photodetecting device according to claim 6,
wherein said insulating layer is formed by stacking a plurality of types of layers whose refractive indices are different from one another.

8. The semiconductor photodetecting device according to claim 5,
wherein said insulating layer is made of a semiconductor material including oxygen.

9. The semiconductor photodetecting device according to claim 5,
wherein said insulating layer is made of one of silicon dioxide and silicon nitride.

10. The semiconductor photodetecting device according to claim 1,
wherein said plurality of pn junction layers are made of a semiconductor material including silicon.

11. The semiconductor photodetecting device according to claim 10,
wherein one of said plurality of pn junction layers is made of one of amorphous silicon, micro-crystal silicon, single-crystal silicon carbide, amorphous silicon carbide, and micro-crystal silicon carbide.

12. The semiconductor photodetecting device according to claim 1, further comprising
an insulating layer that is formed between said pn junction layer and said another pn junction layer, said another pn junction layer being adjacent to said pn junction layer.

13. A method of manufacturing a semiconductor photodetecting device, said method comprising:
forming a first pn junction layer on a substrate;
forming a first insulating layer on the first pn junction layer;
forming a second pn junction layer on the first insulating layer;
forming a second insulating layer on the second pn junction layer; and
forming a third pn junction layer on the second insulating layer,
wherein in said forming of the first pn junction layer, the second pn junction layer, and the third pn junction layer, band gaps of the first pn junction layer, the second pn junction layer, and the third pn junction layer are different from one another.

14. The method according to claim 13,
wherein said forming of the second pn junction layer and the third pn junction layer includes forming the second pn junction layer and the third pn junction layer by forming one of a polycrystalline film and an amorphous film and then applying the film with one of heating and irradiating with light on to change crystallinity of the film.

15. The method according to claim 14,
wherein said forming of the second pn junction layer and the third pn junction layer includes forming the second pn junction layer and the third pn junction layer by irradiating laser light on the film to change crystallinity of the film.

16. The method according to claim 15,
wherein said forming of the first insulating layer and the second insulating layer includes forming the first insulating layer and the second insulating layer by implanting an impurity into the first pn junction layer and the second pn junction layer by ion implantation.

17. The method according to claim 16,
wherein said forming of the first insulating layer and the second insulating layer includes forming the first insulating layer and the second insulating layer by implanting oxygen ion by the ion implantation.

18. The method according to claim 13,
wherein said forming of the first pn junction layer, the second pn junction layer, and the third pn junction layer includes forming the first pn junction layer, the second pn junction layer, and the third pn junction layer by epitaxial growth.

19. The method according to claim 13,
wherein said forming of the first pn junction layer includes forming of the first pn junction by positioning a pn junction in the first pn junction layer to have highest photodetecting sensitivity to red light,
said forming of the second pn junction layer includes forming of the second pn junction layer by positioning a pn junction in the second pn junction layer to have highest photodetecting sensitivity to green light, and
said forming of the third pn junction layer includes forming of the third pn junction layer by positioning a pn junction in the third pn junction layer to have highest photodetecting sensitivity to blue light.

20. The method according to claim 13,
wherein said forming of the first insulating layer and the second insulating layer includes forming of the first insulating layer and the second insulating layer by implanting an impurity into the first pn junction layer and the second pn junction layer by ion implantation.
